(19) United States
(12) Patent Application Publication
(10) Pub. No.: US 2026/0363043 A1
(43) Pub. Date: Nov. 12, 2026

(54) COBALT CONTAINING SINGLE BARRIER AND LINER FOR INTERCONNECT FORMATION

(71) Applicant: Applied Materials, Inc., Santa Clara, CA (US)

(72) Inventors: Tianyi SUN, Santa Clara, CA (US); Kevin KASHEFI, Dublin, CA (US)

(21) Appl. No.: 19/668,075

(22) Filed: May 5, 2026

Related U.S. Application Data
(60) Provisional application No. 63/800,770, filed on May 6, 2025.

(51) Int. Cl. H10W 20/00; H10P 14/43; H10P 14/44; H10P 70/00

(52) U.S. Cl. CPC H10W 20/035; H10P 14/43; H10P 14/44; H10P 70/27; H10W 20/052; H10W 20/056

(57) ABSTRACT

A method of forming a metal interconnect in a semiconductor structure is disclosed. The method includes forming an opening in a dielectric layer, optionally removing contaminants from surfaces of the opening, and optionally depositing a thin barrier layer. A barrier‑liner layer comprising a cobalt‑based alloy with one or more alloying elements is deposited within the opening. An amount of the alloying elements at a surface of the barrier‑liner layer is optionally adjusted by sputtering to preferentially remove cobalt. A gap‑fill process is then performed to form a metal interconnect within the opening. The disclosed method provides improved adhesion, reduced electromigration, and enhanced diffusion barrier performance while allowing increased metal fill volume for semiconductor interconnects.

### CROSS-REFERENCE TO RELATED APPLICATIONS

This application claims the benefit of United States provisional patent application serial number 63/800,770, filed May 6, 2025, which is herein incorporated by reference.

### BACKGROUND

### FIELD

Embodiments described herein generally relate to semiconductor device fabrication, and more particularly, to methods of forming interconnect structures.

### DESCRIPTION OF THE RELATED ART

The miniaturization of semiconductor circuit elements has reached a point where feature sizes of 20 nm and less are fabricated on a commercial scale. As the critical dimensions continue to decrease in size, new challenges arise for reliably producing high aspect ratio features for the next generation of semiconductor devices. In fabrication of an integrated circuit, as the size of features shrinks, there is not enough volume within the features to form interconnect structures (such as contacts and interconnects) with a large enough volume of conductive material. When features are not filled with a sufficient volume of conductive material, the interconnect structures lack reliability and have undesirably high resistive‑capacitance (RC) delays.

Accordingly, there is a need for methods for improved interconnect structure formation in electronic devices.

### SUMMARY

Embodiments of the disclosure include a method of forming a metal interconnect in a semiconductor structure, comprising: removing contaminants from a surface of a dielectric layer formed on a surface of a substrate; depositing a barrier layer on the surface of the dielectric layer; depositing a barrier-liner layer on the barrier layer disposed on the surface of the dielectric layer, wherein the barrier-liner layer comprises an alloy, and the alloy comprises cobalt (Co) and one or more alloying elements selected from a group that comprises copper (Cu), ruthenium (Ru), iridium (Ir), rhodium (Rh), niobium (Nb), titanium (Ti), iron (Fe), tantalum (Ta), manganese (Mn), zirconium (Zr), chromium (Cr), and zinc (Zn); processing a surface of the deposited barrier-liner layer to adjust an amount of the one or more alloying elements on the surface of the deposited barrier-liner layer; and performing a gap fill process to form a metal interconnect within the surface of the dielectric layer.

Other embodiments of the disclosure include a method of forming a metal interconnect in a semiconductor structure, comprising: depositing a barrier-liner layer on a surface of a dielectric layer, wherein the barrier-liner layer comprises an alloy, and the alloy comprises cobalt (Co) and one or more alloying elements selected from a group that comprises copper (Cu), ruthenium (Ru), iridium (Ir), rhodium (Rh), niobium (Nb), titanium (Ti), iron (Fe), tantalum (Ta), manganese (Mn), zirconium (Zr), chromium (Cr), and zinc (Zn); and performing a gap fill process to form a metal interconnect within the surface of the dielectric layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic top view of a multi-chamber substrate processing system in accordance with one or more embodiments described herein.

FIG. 2 illustrates an example chamber substrate processing system in accordance with one or more embodiments described herein.

FIG. 3 illustrates a method of both the optional and non-optional steps of forming a metal interconnect in a semiconductor structure.

FIGS. 4A, 4B, 4C and 4D are cross-sectional views of a portion of the semiconductor structure corresponding to various states, including optional blocks of the method of FIG. 3.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The miniaturization of semiconductor circuit elements has reached a point where feature sizes of 20 nm and less are fabricated on a commercial scale. As the size of the features shrinks, there is less volume available within the features for a conductive material. As a result, interconnect structures lack reliability and have increased resistive-capacitance (RC) delays. Embodiments herein relate to increasing the volume of conductive material within a feature of an electronic device by replacing a barrier layer and liner layer formed within the features with a single barrier-liner layer that can function as both a barrier layer and liner layer. In certain embodiments, the barrier-liner layer alone functions as both a diffusion barrier and a liner, thereby eliminating the need for a separately deposited barrier layer, and the space that the barrier layer would undesirably take up in a smaller device feature. Advantageously, the single barrier-liner layer consumes less volume than the separate barrier layer and liner layer and thus, allows for more conductive material to be positioned within the feature.

### EXEMPLARY SUBSTRATE PROCESSING SYSTEM

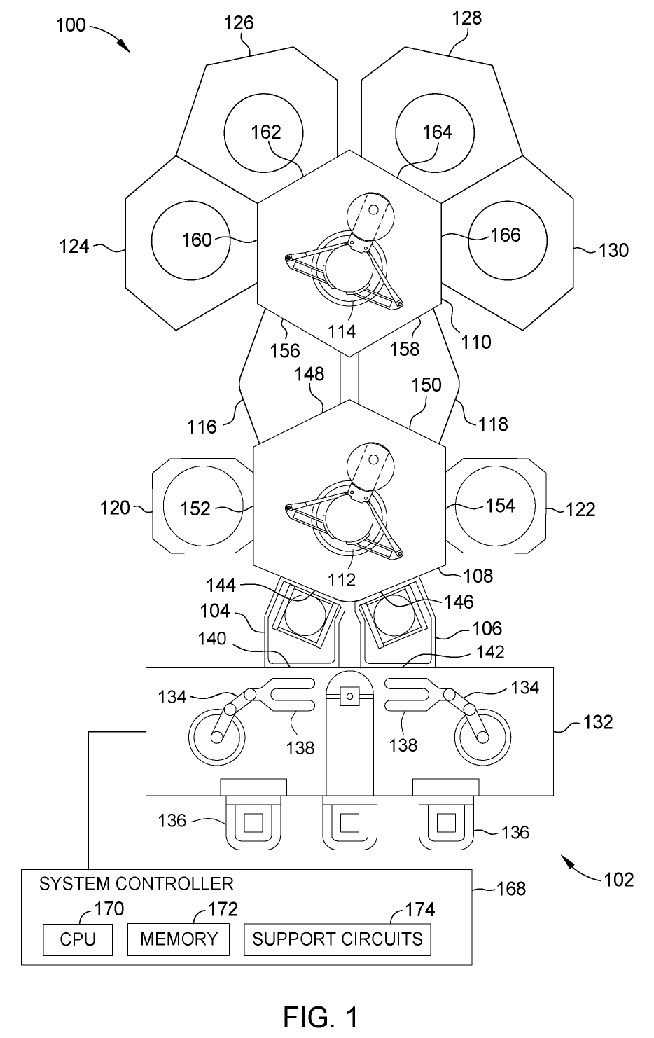

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 400 Torr) or a vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura^{®}, Producer^{®} or Centura^{®} integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114, and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber, Volta™ CVD/ALD chamber, or Encore™ PVD chambers available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate the performance of the processing system 100.

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

### PROCESSING CHAMBER EXAMPLES

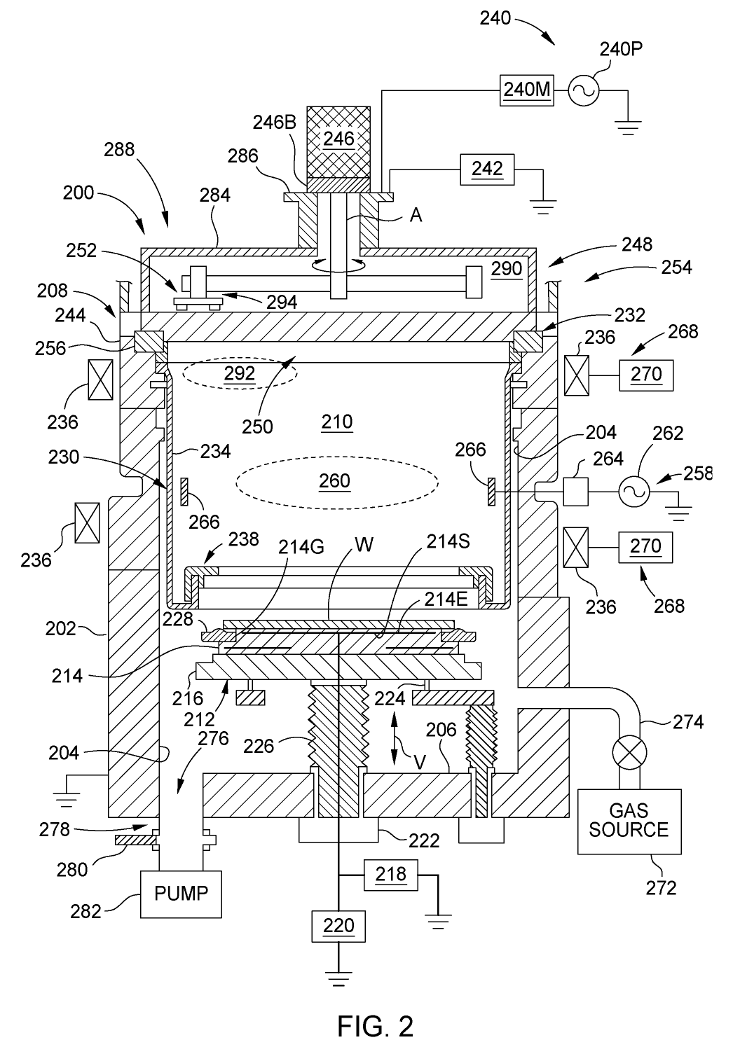

FIG. 2 is a schematic view of an exemplary physical vapor deposition (PVD) chamber 200 that can be the processing chamber 120, 122, 124, 126, 128, 130 of the processing system 100 shown in FIG. 1.

The processing chamber 200 includes a chamber body 202 having sidewalls 204, a bottom wall 206, and an upper process assembly 208 that enclose a processing region 210 or plasma zone. The chamber body 202 is typically fabricated from welded plates of stainless steel or a unitary block of aluminum. The sidewalls 204 may be formed of aluminum and the bottom wall 206 may be formed of a stainless steel plate. The sidewalls 204 generally contain a slit valve (not shown) to provide entry and egress of a substrate W from the processing chamber 200.

The processing chamber 200 further includes a pedestal assembly 212 that generally includes a substrate support 214 sealingly coupled to a platform housing 216. The substrate support 214 may be formed of aluminum or ceramic. The substrate support 214 has a substrate receiving surface 214S that receives and supports the substrate W during processing, and a peripheral edge 214G that terminates before an overhanging edge of the substrate W. The substrate support 214 may be an electrostatic chuck, a ceramic body, a heater or a combination thereof. In one embodiment, the substrate support 214 is an electrostatic chuck that includes a dielectric body having an electrode 214E, embedded therein. The dielectric body is typically fabricated from a high thermal conductivity dielectric material such as pyrolytic boron nitride, aluminum nitride, silicon nitride, alumina, or an equivalent material. In one embodiment, the electrode 214E is configured so that when a DC voltage is applied to the electrode 214E, by an electrostatic chuck power supply 218, a substrate W disposed on the substrate receiving surface 214S will be electrostatically chucked thereto to improve the heat transfer between the substrate W and the substrate support 214. In another embodiment, an impedance controller 220 is also coupled to the electrode 214E so that a voltage can be maintained on the substrate W during processing to affect the plasma interaction with the surface of the substrate W. The platform housing 216 is typically fabricated from a metallic material such as stainless steel or aluminum. A cooling plate (not shown) is generally disposed within the platform housing 216 to thermally regulate the substrate support 214.

The pedestal assembly 212 is supported from the bottom wall 206 by a lift mechanism 222, which is configured to move the pedestal assembly 212 between an upper processing position and a lower transfer position. Additionally, in the lower transfer position, lift pins 224 are moved through the pedestal assembly 212 to position the substrate W a distance from the pedestal assembly 212 to facilitate the exchange of the substrate W with a substrate transfer mechanism disposed exterior to the processing chamber 200, such as a single blade robot (not shown). A bellows 226 is typically disposed between the pedestal assembly 212 and the bottom wall 206 to isolate the processing region 210 from the interior of the pedestal assembly 212 and the exterior of the processing chamber 200. The pedestal assembly 212 supports a deposition ring 228 along with the substrate W during processing.

The processing chamber 200 further includes a process kit 230 that includes various components easily removable from the processing chamber 200, for example, to clean sputtering deposits off the component surfaces, replace or repair eroded components, or to adapt the processing chamber 200 for other processes. The process kit 230 further includes an isolator ring assembly 232, a grounded shield 234, and lower magnetic coil assemblies 236.

Components in the upper process assembly 208 of the processing chamber 200 in cooperation with the grounded shield 234, the pedestal assembly 212, and a cover ring 238 confine the plasma formed in the processing region 210 to the region above the substrate W.

The upper process assembly 208 includes a radio frequency (RF) source 240, a direct current (DC) source 242, an adaptor 244, a motor 246, and a lid assembly 248. The lid assembly 248 generally includes a target 250, a magnetron system 252 and a lid enclosure 254. The upper process assembly 208 is supported by the sidewalls 204 when in a closed position, as shown in FIG. 2. A ceramic target isolator 256 is disposed between the isolator ring assembly 232, the target 250, and the adaptor 244 to prevent vacuum leakage therebetween. The adaptor 244 is sealably coupled to the sidewalls 204, and is configured to help with the removal of the upper process assembly 208 and isolator ring assembly 232.

When in the processing position, the target 250 is disposed adjacent to the adaptor 244, and is exposed to the processing region 210. The target 250 contains material that is deposited on the substrate W during a PVD, or sputtering process. The isolator ring assembly 232 is disposed between the target 250 and the grounded shield 234 and the chamber body 202 to electrically isolate the target 250 from the grounded shield 234 and the chamber body 202.

During processing, the target 250 is biased relative to a grounded region of the processing chamber 200 (e.g., the chamber body 202 and the adaptor 244) by a power source disposed in the RF source 240 and/or the DC source 242. In one embodiment, the RF source 240 includes an RF power source 240P and an RF match 240M that are configured to efficiently deliver RF energy to the target 250. In one example, the RF power source 240P is capable of generating RF currents at a frequency of between about 13.56 MHz and about 228 MHz at powers between about 0 and about 5 kilowatts (kW). In one example, the DC source 242 is capable of delivering between about 0 and about 10 kW of DC power.

The central portion of the processing chamber 200 includes an inductive coil assembly 258 that is positioned within a central region of the process kit 230, and is configured to form an inductively coupled plasma 260 during processing that is used to ionize atoms ejected from the target 250 and/or ionize process gases during processing. The inductive coil assembly 258 includes an RF power source 262 and an impedance match 264 that are coupled to a coil 266 that is disposed within the processing region 210 of the processing chamber 200. In some embodiments, the coil 266 includes a single turn coil that is formed from a metal. In one configuration, the coil 266 is formed from a conductive material that is made of the same material as the target 250. In some configurations, the RF power source 262 is capable of generating RF currents at a frequency of between about 13.56 MHz and about 228 MHz at powers between about 0 and about 5 kilowatts (kW).

In some embodiments, the central portion of the processing chamber 200 also includes one or more electromagnet assemblies 268. The electromagnet assemblies 268 each include a current source 270 that is configured to bias the magnetic coil assemblies 236, respectively. The one or more electromagnet assemblies are positioned adjacent to the central region of the process kit 230, and are each configured to provide a generated magnetic field within the processing region 210 to help alter and/or shape the radial distribution of the plasma formed with the processing region 210 during processing. In some configurations, the current source 270 is capable of generating a DC or RF current or voltage at a power between about 0 and about 5 kW.

During processing, a gas, such as argon, is supplied to the processing region 210 from a gas source 272 via conduits 274. The gas source 272 may include process gas, such as argon (Ar), helium (He), neon (Ne), krypton (Kr), nitrogen (N₂), hydrogen (H₂), which is capable of energetically impinging upon and sputtering material from the target 250. The gas source 272 may also include a reactive gas, such as one or more of an oxygen-containing gas or a nitrogen-containing gas, which is capable of reacting with the sputtering material to form a layer on a substrate. Spent process gas and byproducts are exhausted from the processing chamber 200 through exhaust ports 276 that receive spent process gas and direct the spent process gas to an exhaust conduit 278 having an adjustable position gate valve 280 to control the pressure in the processing region 210 in the processing chamber 200. The exhaust conduit 278 is connected to one or more exhaust pump 282, such as a cryopump. Typically, the pressure of the sputtering gas in the processing chamber 200 during processing is set to sub-atmospheric levels, such as a vacuum environment, for example, a pressure of about 0.6 mTorr to about 400 mTorr. In one embodiment, the processing pressure is set to about 20 mTorr to about 100 mTorr. A plasma is formed between the substrate W and the target 250 from the gas. Ions within the plasma are accelerated toward the target 250 and cause material to become dislodged from the target 250. The dislodged target material is deposited on the substrate.

The lid enclosure 254 generally includes a conductive wall 284, a center feed 286 and a shielding 288. In this configuration, the conductive wall 284, the center feed 286, the target 250 and a portion of the motor 246 enclose and form a back region 290. The back region 290 is a sealed region disposed on the back side of the target 250 and is generally filled with a flowing liquid to remove the heat generated at the target 250 during processing. In one embodiment, the conductive wall 284 and the center feed 286 are configured to support the motor 246 and the magnetron system 252, so that the motor 246 can rotate the magnetron system 252 during processing. In one embodiment the motor 246 is electrically isolated from the RF or DC power delivered from the power supplies by use of a dielectric layer 246B, such as Delrin, G10, or Ardel.

The shielding 288 may include one or more dielectric materials that are positioned to enclose and prevent the RF energy delivered to the target 250 from interfering with and affecting other processing chambers disposed in the processing system (shown in FIG. 1). In one configuration, the shielding 288 may be formed of a Delrin, G10, Ardel or other similar material and/or a thin grounded sheet metal RF shield.

To provide efficient sputtering, the magnetron system 252 is positioned in back of the target 250 in the upper process assembly 208 to create a magnetic field in the processing region 210 adjacent a sputtering surface 250S of the target 250, which creates a magnetron-induced plasma 292. The magnetic field by magnetron system 252 is created to trap electrons and ions to thereby increase the plasma density in the magnetron-induced plasma 292 region and to thereby also increase the sputtering rate. According to one embodiment of the disclosure, the magnetron system 252 includes a source magnetron assembly 294 that includes an outer pole (not shown) and an inner pole (not shown). The magnetron system 252 is rotated about a central axis A by use of the motor 246. In some embodiments, a “closed loop” magnetron configuration is formed within the magnetron system 252 such that the outer pole of the magnetron surrounds the inner pole of the magnetron forming a gap between the poles that is a continuous loop. In the closed loop configuration, the magnetic fields that emerge and reenter through a surface of the target form a “closed loop” pattern that can be used to confine electrons near the surface of the target in a closed pattern, which is often called a “racetrack” type pattern. A closed loop, as opposed to the open-loop, magnetron configuration is able to confine electrons and generate a high density plasma near the sputtering surface 250S of the target 250 to increase the sputtering yield. In some other embodiments, an “open loop” magnetron configuration is formed within the magnetron system 252 such that the outer pole of the magnetron surrounds the inner pole of the magnetron forming a gap between the poles that is a continuous loop. In an open loop magnetron configuration, the electrons trapped between the inner and outer poles will migrate, leak out and escape from the B-fields created at open ends of the magnetron, thus only holding the electrons for a short period of time during the sputtering process due to the reduced confinement of the electrons. It has been found that the use of an open loop magnetron configuration, can provide significant step coverage improvements and provide an improved material composition uniformity across the substrate surface, when used in conjunction with the RF and DC sputtering of multi-compositional targets described herein.

In some embodiments, the impedance controller 220 is replaced by an RF source (not shown) and an impedance match (not shown) that are coupled to the electrode 214E. In some embodiments, the RF power source is capable of generating RF currents at a frequency of between about 13.56 MHz and about 228 MHz at powers between about 0 and about 5 kW.

A program (or computer instructions) readable by a system controller, such as the system controller 168 shown in FIG. 1, determines which tasks are performable on a substrate. Preferably, the program is software readable by the system controller 138 that includes code to perform tasks relating to monitoring, execution and control of the movement and various process recipe tasks and recipe steps being performed in the processing system 100. For example, the system controller 168 can include program code that includes a substrate positioning instruction set to operate the pedestal assembly 212, a gas flow control instruction set to operate gas flow control valves to set a flow of sputtering gas to the processing chamber 200, a gas pressure control instruction set to operate a throttle valve or gate valve to maintain a pressure in the processing chamber 200, a temperature control instruction set to control a temperature control system (not shown) in the pedestal assembly 212 or sidewalls 204 to set temperatures of the substrate W or sidewalls 204, respectively, and a process monitoring instruction set to monitor the process in the processing chamber 200.

### PROCESSING METHODS

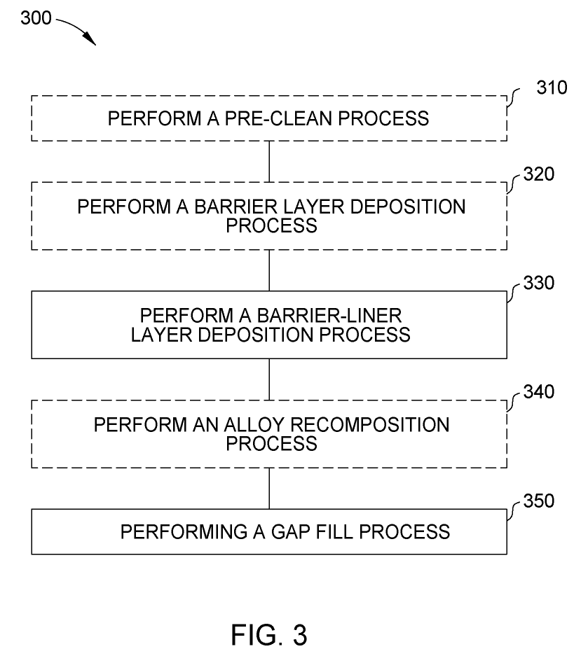

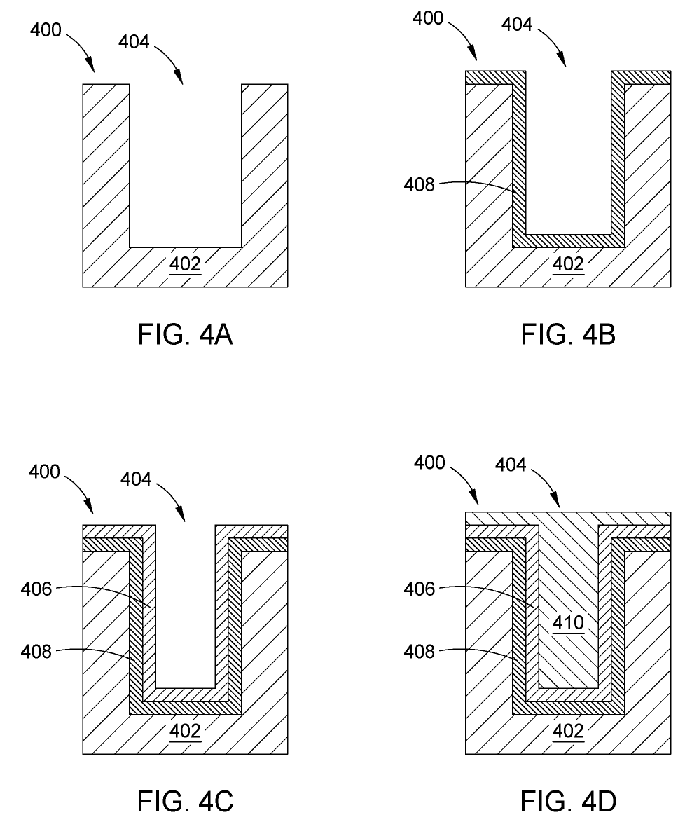

FIG. 3 depicts a process diagram of a method 300 of forming a metal interconnect 410 in a semiconductor structure 400, according to one or more embodiments of the present disclosure. FIGS. 4A, 4B, 4C and 4D are cross-sectional views of a portion of the semiconductor structure 400 corresponding to various states of the method 300. The embodiments shown in FIGS. 4A, 4B, 4C and 4D illustrate only partial schematic views of the semiconductor structure 400, and the semiconductor structure 400 may contain any number of transistor sections and additional materials having aspects as illustrated in the figures. Additionally, while the embodiment shown in the method illustrated in FIG. 3 is described sequentially, other process sequences that include one or more operations that have been omitted and/or added, and/or have been rearranged in another desirable order fall within the scope of the embodiments of the disclosure provided herein.

As shown in FIG. 4A, the semiconductor structure 400 includes a dielectric layer 402 patterned with an opening (e.g., a trench) 404 through the dielectric layer 402 on a substrate (not shown). The dielectric layer 402 may be formed of silicon oxide (SiO₂) or a low-k dielectric material, such as carbon-containing silicon oxides (SiOC). In some embodiments, a metal layer (not shown) such as tungsten (W) or copper (Cu) is formed at the bottom of the opening 404. The opening 404 may have a critical dimension (CD) of less than about 10 nm.

The substrate (not shown) may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate may have various dimensions, such as 300 mm, 400 mm or 450 mm diameter wafers, as well as rectangular or square panels.

The method 300 begins with optional block 310, in which an optional pre-clean process is performed to remove contaminants, such as MoOx (molybdenum oxide), formed within an opening 404 formed through a dielectric layer 402. Hence, the pre-clean process removes contaminants on and/or within the surface of the dielectric layer 402. The pre-clean process may include etching the inner surfaces of the opening 404 by a remote plasma assisted chemical etch process using H₂/Ar gas performed in a processing chamber, such as Aktiv™ Preclean (APC) chamber available from Applied Materials of Santa Clara, Calif., or a capacitively coupled plasma (CCP) chemical etch process with ion bombardment using H₂/Ar gas performed in a processing chamber, such as Preclean XT chamber available from Applied Materials of Santa Clara, Calif. The pre-clean process may be performed in a pre-clean chamber, such as the processing chamber 122 shown in FIG. 1.

In optional block 320, an optional barrier layer deposition process is performed to deposit an optional barrier layer 408 within the opening 404, as shown in FIG. 4B. In other words, an optional barrier layer 408 is deposited within the opening 404 formed through a dielectric layer 402. In some embodiments, the optional barrier layer 408 may be formed of a transition metal such as niobium (Nb), tantalum (Ta) or titanium (Ti), and nitrides thereof, such as tantalum nitride (TaN) or titanium nitride (TiN), and deposited by an atomic layer deposition (ALD) or other suitable deposition process, performed in a processing chamber, such as the processing chambers 124, 126, 128, or 130. In some embodiments, the optional barrier layer 408 can be a conformal layer. In one example, the use of a niobium containing layer as the barrier layer can be beneficial as any nitrogen present in the dielectric layer 402 can diffuse into and react with the deposited niobium material and form niobium nitride (NbN). The formation of NbN can also help control and/or minimize the formation of a molybdenum nitride layer that is formed due to a molybdenum containing layer being positioned over and in contact with the niobium containing barrier layer. The optional barrier layer 408 may have a thickness of about 5 angstroms. In some embodiments, the optional barrier layer 408 may have a thickness of about 2 to 12 angstroms. While not necessary, the implementation of optional block 320 can aid in preventing electromigration from the metal interconnect 410 that will be formed, which will be further explained in block 350.

In block 330, a barrier-liner deposition process is performed to deposit a barrier-liner layer 406 within the opening 404 of the dielectric layer 402, as shown in FIG. 4C. Hence, the barrier-liner layer 406 is deposited on the surface of the dielectric layer 402. If optional block 320 is implemented, the barrier-liner layer 406 is deposited on the optional barrier layer 408, and if the optional block 320 is not implemented, the barrier-liner layer 406 is deposited within the opening 404 on the dielectric layer 402 without a separately deposited barrier layer 408. The barrier-liner layer 406 may be formed of a cobalt (Co) alloy that includes one or more of the following alloying elements selected from a group that includes copper (Cu), ruthenium (Ru), iridium (Ir), rhodium (Rh), niobium (Nb), titanium (Ti), iron (Fe), tantalum (Ta), manganese (Mn), zirconium (Zr), chromium (Cr), and zinc (Zn). In some embodiments, the atomic percentage of the alloying element can be between about 5 and about 20 atomic percent for a cobalt alloy. In some embodiments, the atomic percentage may vary depending on the selected alloying element. It is believed that cobalt alloys selected with an element from a first group of elements, which includes copper (Cu), ruthenium (Ru), iridium (Ir), or rhodium (Rh), can be used to improve the adhesion between the metal interconnect 410 and the surface formed within the opening 404. It is believed that cobalt alloys that include an element from a second group of elements, which includes niobium (Nb), titanium (Ti), iron (Fe), tantalum (Ta), manganese (Mn), zirconium (Zr), chromium (Cr), and zinc (Zn), can also improve the diffusion barrier properties by preventing electromigration of the metal interconnect 410 into the dielectric layer 402, as well as preventing any nitrogen in the dielectric layer 402 from diffusing into the metal interconnect 410. Hence, the cobalt alloy can be formed with elements from either one of or both groups of elements. Such ternary alloy, (multi-component cobalt alloys or high entropy alloys) can be useful to optimize both barrier and liner functionalities of the barrier-liner layer 406. In some embodiments, the alloying element can be selected from a preferred group that includes niobium (Nb), titanium (Ti), and copper (Cu). In other embodiments, the alloying element can be selected from another preferred group that includes iron (Fe), zirconium (Zr), tantalum (Ta), and manganese (Mn).

In some embodiments, the temperature range for the deposition processes of optional block 320 and block 330 can occur at temperatures of about -20°C to 275°C and at pressures of about 0.1 mTorr to 10 mTorr. In one embodiment, argon (Ar) may be used to sputter a target that is biased at a DC power level that is between 20 kilowatts (kW) and 35 kW, such as about 30 kW. While the deposited films are conformal in one embodiment, in other embodiments, the deposited films may be non-conformal. In some embodiments, one of the deposited films from blocks 320, 330 may have a crystalline structure, while in other embodiments, one or more of the deposited films have an amorphous structure. It is believed that deposited amorphous films can aid the film’s barrier properties, such as preventing electromigration of the metal interconnect 410 into the dielectric layer 402 and preventing any nitrogen in the dielectric layer 402 from diffusing into the metal interconnect 410.

The cobalt alloys for the barrier-liner layer 406 may preferentially be deposited by physical vapor deposition (PVD). The thickness of the barrier-liner layer 406 may be about 5 to about 25 angstroms, and yet in other embodiments, the thickness of the barrier-liner layer 406 may be about 10 to about 20 angstroms. In one embodiment, the barrier-liner layer 406 may have a thickness of about 15 angstroms. By reducing the thickness of the optional barrier layer 408 and the barrier-liner layer 406, the thickness of the metal interconnect 410 can be maximized. This improves device performance, while reducing processing steps that reduce device manufacturing process complexity and improve tool reliability. One benefit of the use of a cobalt alloy as the barrier-liner layer 406 is that it provides a surface that aids the metal used in the fill process to flow within the surface of the dielectric layer 402 to form the metal interconnect 410. In one embodiment, the cobalt alloy comprises cobalt with about 5 to 25 atomic percent niobium, such as 10 atomic percent niobium deposited by a PVD process. In other embodiments, the barrier-liner layer 406 may be formed of tantalum (Ta), titanium (Ti), or nitrides thereof, such as tantalum nitride (TaN) or titanium nitride (TiN), tungsten (W), molybdenum (Mo), or in stack, or alloys thereof, and can be deposited by an atomic layer deposition (ALD) or other suitable deposition process.

In optional block 340, an optional alloy recomposition process may be performed on the barrier-liner layer 406 where the composition of the barrier-liner layer 406 is adjusted. The optional alloy recomposition process results in a higher percentage of the alloying elements within the cobalt alloy, i.e., lowering the percentage of cobalt that was deposited in block 330. This includes biasing the substrate W (not pictured in FIGS. 4A-4D, but would be located underneath the dielectric layer 402), and sputtering, by use of a noble gas such as argon, the barrier-liner layer 406. In transient conditions, the argon will be able to preferentially “sputter” the base cobalt atoms due to their higher sputter rate (or sputter yield) versus the alloying material (e.g., Nb) when exposed to the inert gas containing plasma (e.g., Ar plasma), and thus leaving behind a greater concentration of the alloying elements on the surface of the barrier-liner layer 406. Thus, in some embodiments, cobalt has a higher sputter yield than the alloying material disposed within the barrier-liner layer 406 during the process(es) performed during block 340. Hence, the surface of the barrier-liner layer 406 has a composition unlike that of the rest of the barrier-liner layer 406, where the surface of the barrier-liner layer 406 has a higher composition of the alloying elements that were left behind after applying the bias to the substrate during the sputtering process. In one embodiment, the substrate W is biased at powers of about 50 to 300 watts, at a frequency of about 13.56 MHz, at pressures of about 0.1 to about 50 mTorr, and substrate temperatures of about -20°C to about 275°C. In the case the alloying element is niobium, the higher concentration of niobium would encourage a higher concentration of niobium nitride to be formed during subsequent processing and assist in preventing electromigration of the metal interconnect 410 as discussed above.

In some embodiments, the recomposition process increases a concentration of the one or more alloying elements at the exposed surface of the barrier‑liner layer 406 by at least about 2 atomic percent, such as by about 2 to 10 atomic percent. In other embodiments, the surface concentration increase relative to the bulk composition of the barrier-liner layer 406 may be up to about 30 atomic percent.

In block 350, whether or not the optional block 340 is performed, a gap fill process is performed to form a metal interconnect 410 on a surface of the barrier-liner layer 406 within the opening 404 formed through the dielectric layer 402, as shown in FIG. 4D. Hence, the metal interconnect 410 is formed within the surface of the dielectric layer 402. The gap fill process may include depositing a metal seed layer on the barrier-liner layer 406 within the opening 404, by physical vapor deposition (PVD), chemical vapor deposition (CVD), or other suitable deposition process and subsequently thickening the metal seed layer to completely fill the opening 404 during a reflow anneal. The metal interconnect 410 may include copper (Cu), a copper (Cu) alloy, aluminum (Al, an aluminum (Al) alloy, tungsten (W), a tungsten (W) alloy, molybdenum (Mo), or a molybdenum (Mo) alloy.

While the foregoing is directed to embodiments of the invention, other and further embodiments of the invention may be devised without departing from the basic scope thereof, and the scope thereof is determined by the claims that follow.

What is claimed is:

1. A method of forming a metal interconnect in a semiconductor structure, comprising:
removing contaminants from a surface of a dielectric layer formed on a surface of a substrate;
depositing a barrier layer on the surface of the dielectric layer;
depositing a barrier-liner layer on the barrier layer disposed on the surface of the dielectric layer, wherein the barrier-liner layer comprises an alloy, and the alloy comprises cobalt (Co) and one or more alloying elements selected from a group that comprises copper (Cu), ruthenium (Ru), iridium (Ir), rhodium (Rh), niobium (Nb), titanium (Ti), iron (Fe), tantalum (Ta), manganese (Mn), zirconium (Zr), chromium (Cr), and zinc (Zn);
processing a surface of the deposited barrier-liner layer to adjust an amount of the one or more alloying elements on the surface of the deposited barrier-liner layer; and
performing a gap fill process to form a metal interconnect within the surface of the dielectric layer.

2. The method of claim 1, wherein the barrier layer comprises niobium (Nb) and the alloying element in the barrier-liner layer is niobium (Nb).

3. The method of claim 2, wherein the dielectric layer comprises nitrogen.

4. The method of claim 2, wherein the barrier-liner layer comprises about 5 to about 20 atomic percent of the alloying element.

5. The method of claim 1, wherein the barrier-liner layer is obtained by use of a physical vapor deposition (PVD) process and the barrier layer comprises a conformal layer that is formed by use of an atomic layer deposition (ALD) process.

6. The method of claim 1, wherein the metal interconnect comprises material selected from the group consisting of copper (Cu), a copper (Cu) alloy, aluminum (Al), an aluminum (Al) alloy, tungsten (W), a tungsten (W) alloy, molybdenum (Mo), and a molybdenum (Mo) alloy.

7. The method of claim 1, wherein a thickness of the barrier layer is about 5 angstroms.

8. The method of claim 1, wherein processing the surface of the deposited barrier-liner layer comprises sputtering the surface of the barrier-liner layer, and wherein sputtering preferentially removes cobalt versus the one or more alloying elements.

9. A method of forming a metal interconnect in a semiconductor structure, comprising:
depositing a barrier-liner layer on a surface of a dielectric layer, wherein the barrier-liner layer comprises an alloy, and the alloy comprises cobalt (Co) and one or more alloying elements selected from a group that comprises copper (Cu), ruthenium (Ru), iridium (Ir), rhodium (Rh), niobium (Nb), titanium (Ti), iron (Fe), tantalum (Ta), manganese (Mn), zirconium (Zr), chromium (Cr), and zinc (Zn); and
performing a gap fill process to form a metal interconnect within the surface of the dielectric layer.

10. The method of claim 9, wherein the metal interconnect comprises a material selected from the group consisting of copper (Cu), a copper (Cu) alloy, aluminum (Al), an aluminum (Al) alloy, tungsten (W), a tungsten (W) alloy, molybdenum (Mo), and a molybdenum (Mo) alloy.

11. The method of claim 9, wherein the barrier-liner layer is obtained by use of a physical vapor deposition (PVD) process.

12. The method of claim 9, wherein a thickness of the barrier-liner layer is between about 10 angstroms (Å) and 20 Å.

13. The method of claim 9, wherein the barrier-liner layer comprises about 5 to about 20 atomic percent of the alloying element.

14. The method of claim 13, wherein the dielectric layer comprises nitrogen.

15. The method of claim 9, further comprising:
prior to performing a gap fill process, adjusting an amount of the one or more alloying elements on a surface of the deposited barrier-liner layer, wherein adjusting the amount of the one or more alloying elements on a surface of the deposited barrier-liner layer comprises sputtering the surface of the barrier-liner layer, and the sputtering preferentially removes cobalt versus the one or more alloying elements.

16. The method of claim 9, further comprising, prior to depositing the barrier-liner layer, depositing a barrier layer on the surface of the dielectric layer.

17. The method of claim 16, wherein the barrier layer is niobium (Nb) and the alloying element in the barrier-liner layer comprises niobium (Nb), titanium (Ti), or copper (Cu).

18. The method of claim 16, wherein the barrier layer comprises a conformal layer that is formed by use of an atomic layer deposition (ALD) process.

19. The method of claim 16, wherein a thickness of the barrier layer is about 5 angstroms.

20. The method of claim 9, wherein the alloying element in the barrier-liner layer comprises niobium (Nb), titanium (Ti), or copper (Cu).
